(19) United States
(12) Patent Application Publication
(10) Pub. No.: US 2002/0045344 A1
(43) Pub. Date: Apr. 18, 2002

(54) METHOD OF FORMING POLYCRYSTALLINE COSI2 SALICIDE AND PRODUCTS OBTAINED THEREOF

(76) Inventors: QUINGFENG WANG, PLANO, TX (US); KAREN MAEX, HERENT (BE)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/309,455

(22) Filed: Jun. 26, 1998

Related U.S. Application Data
(63) Continuation of application No. 09/055,645, filed on Apr. 6, 1998, now abandoned.
Application No. 09/055,645 is a continuation-in-part of application No. 08/658,182, filed on Jun. 4, 1996.

(51) Int. Cl. H01L 21/44

(52) U.S. Cl. 438/683

(57) ABSTRACT

The present invention is related to a method of forming a polycrystalline cobaltdisilicide or another near noble metal silicide on a silicon substrate. The method comprises the steps of depositing a layer or layers comprising cobalt (Ni, Pd, Pt) and refractory metal on at least a part of said substrate, said part comprising at least a first and a second part, said second part being covered; thereafter heating said silicon substrate in a first heating step and a second heating step and therebetween treating said substrate with at least one chemical solution, said chemical solution selectively etching non-silicidecobalt (or Ni, Pd, Pt) and said refractory metal and cobalt-refractory (or Ni, Pd, Pt-refractory) metal alloys from said substrate except from said first part.

RELATED APPLICATIONS

The present Patent Application is a continuation in part of U.S. patent application Ser. No. 09/055645, which is a continuation in part of U.S. patent application Ser. No. 08/658,182, and claims the benefit of the corresponding priorities.

### FIELD OF THE INVENTION

The present invention relates to the field of semiconductor device processing. More particularly, the present invention relates to a method for the fabrication of CoSi₂ salicides and other near noble metal suicides such as NiSi, PtSi, Pd₂Si.

### BACKGROUND OF THE INVENTION

Silicides are known in the art. Metal silicide thin films are commonly used in microelectronic circuits for a variety of applications such as interconnects, contacts and for the formation of transistor gates. Cobalt disilicide (CoSi₂) and mainly Titanium disilicide (TiS₂) are preferentially used in Ultra or Large Scale Integrated Semiconductor devices with submicron design rules. CoSi₂ and TiSi₂ silicide phases are formed through the reaction of Cobalt and Titanium with silicon to form Cobalt disilicide (CoSi₂) and Titanium disilicide (TiSi₂) respectively. The silicide layer has a lower sheet resistance than the sheet resistance of silicon.

It is well known in the state of the art as described in U.S. Pat. No. 5,047,367 incorporated herein by reference to form CoSi₂ and TiSi₂ salicides (self-aligned silicides) on silicon for the manufacture of semiconductor devices. An illustrative embodiment of such salicide technology can be described as follows. To make contact to device regions underlying a dielectric on the surface of the silicon substrate, first an opening or via (contact via) in the dielectric over the region to be contacted is made, and next the contact via is filled with a conductive material. In smaller geometry devices, those of one micron or less, the contact to doped Si is inadequate due to poor contact resistance integrity. For these devices, silicides of refractory or near-noble metals such as titanium or cobalt, are used to shunt the resistance of the highly doped Si. The metal is first deposited followed by an anneal to form the silicide on the substrate in the regions exposed by source, drain, and gate areas. The nonsilicided metal remaining on the dielectric surface and also on the formed silicide is then selectively etched. Because the silicide is formed only on those regions where there is silicon exposed, that is, the active device regions and the gate region, and because the remaining metal can be selectively etched without a masking step, the structure formed by this process is self aligned. This process is an example of self aligned silicide technology (Salicide Technology).

Problem Definition

The more conventional TiSi₂ process cannot be easily scaled down to applications with 0.25 μm down to 0.1 μm or smaller transistor gate lengths because the high resistivity C49 (a specific crystallographical configuration TiSi₂) phase predominates on narrow lines. In contrast, CoSi₂ can be formed on narrow lines without this problem. Nevertheless, the reproducible and reliable formation of thin CoSi₂ on narrow poly-Si transistor gates is still a critical issue.

Recently, CoSi₂ has been introduced in MOS manufacturing. Several CoSi₂ formation processes have been proposed. The deposition of a single layer of Co on Si has been replaced by other process sequences because of the difficult manufacturability of this single layer process. Major problems are its sensitivity to cleaning and its irreproducible yield on narrow lines, partly attributed to a silicide thinning effect at the edges of the silicide lines.

Document U.S. Pat. No. 5,047,367 describes a process for the formation of a titanium nitride/cobalt silicide bilayer for use in semiconductor processing. In this document, it is disclosed that a thin layer of titanium is conformally deposited on a silicon substrate using a sputter deposition technique. A conformal layer of cobalt is next deposited by sputter deposition without removing the substrate from the sputter system. The substrate is then annealed. It is believed that during the process, the titanium first cleans the silicon surface of the substrate of any native oxide. During the anneal, the titanium diffuses upward and the cobalt diffuses downward. The cobalt forms a high quality expitaxial cobalt silicide layer on the silicon substrate. This Ti/Co (Ti at interface) metallization scheme has been introduced to alleviate the requirements for cleaning and has been proposed for its epitaxial CoSi₂ growth. The latter feature though results in a CoSi₂ with a relatively high stress. More importantly, the epitaxial CoSi₂ generates a high stress in the adjacent Si and in the Si underneath. Furthermore, the presence of Ti/Si metals or the interface retards the Co/Si reaction.

### SUMMARY OF THE INVENTION

A CoSi₂ salicidation technology based on a deposition sequence with a thin capping layer preferably made of titanium is developed to improve the uniformity of as formed CoSi₂ and as such to improve the thermal stability of very narrow CoSi₂/Polysilicon stacks and very narrow silicided active areas. Further is disclosed a salicidation technology of other near noble metal (Ni, Pd, Pt) silicides (NiSi, PtSi, Pd₂Si) The silicided polysilicon lines being fabricated according to the invention are very uniform, and can withstand thermal treatments without significant degradation for transistor gate lengths down to 0.08 μm or below. The present invention aims to suggest a method which can be implemented for the self-aligned silicidation in a 0.25 μm CMOS or a 0.18 μm CMOS or a 0.13 μm CMOS process or smaller gate processes such as 0.1 μm or 0.07 μm CMOS processes. The process of the invention has a large process window in terms of silicidation temperature and ambient. This is beneficial for the manufacturability of the process. The silicide is polycrystalline both on monocrystalline and polycrystalline Si substrates and has a low stress resulting in low leakage current levels for large area diodes with narrow dimensions.

The salicidation process of the invention has a wide process window to obtain uniform silicide films more reproducibly than conventional salicidation processes.

The robustness of the Co/Ti (cap) process of the invention makes it very attractive for 0.25 μm CMOS process or 0.18 μm smaller gatelength CMOS processes.

In a first aspect of the present invention, a method of forming a polycrystalline cobalt disilicide on a silicon substrate is disclosed, comprising the steps of:

depositing a first layer comprising cobalt on at least a part of said substrate, said part comprising at least a first and a second part,

depositing a metal getter layer on said first layer; thereafter heating said silicon substrate in a first heating step, said first heating step being performed at a first temperature being such that said first heating step forms a silicidecobalt on said first part;

treating said substrate with at least one chemical solution, said chemical solution selectively removing etching at least the remaining non-silicidecobalt and said getter metal and said cobalt getter metal alloys from said substrate; and thereafter

treating said substrate in a second heating step to thereby form said polycrystalline cobaltdisilicide layer on said first part of said substrate. This second heating step can be combined with subsequent CMOS processing steps if needed. Said second heating step can be performed at a higher temperature than said first temperature.

The deposition of the first layer and metal getter layer can be executed at room temperature or at an elevated temperature or even at lower temperature.

The silicon substrate, e.g. can be a partially processed wafer in a MOS process. The second part of the silicon substrate can be covered with an oxide (SiO₂).

Silicidecobalt is to be understood as any cobalt-silicon compound CoₓSi_{y}. Preferably, the silicidecobalt is cobaltsilicide (CoSi). A getter layer is to be understood as a capping layer on the top of said first layer that is able to absorb desorption of contaminating species out of the substrate, e.g. out of the second part or out of an oxide in said second part. At the same time, the getter layer is having the function of efficiently stopping the penetration of ambient contaminating species into the substrate or into the first layer.

Preferably, during the chemical solution treatment, a passivation layer is grown on top of the silicidecobalt being formed on said first part of said substrate. Said passivation layer is a thin layer. A thin layer is a layer having a thickness that has no negative or detrimental impact on the further processing steps being executed with the silicon substrate. The thin layer can be a 5 nm thick SiO₂ layer on the top of the silicide cobalt. Such chemically grown thin layer protects the silicide during further processing steps. The thermal stability and integrity is achieved by the growth of this chemical oxide during selective etch.

In a second aspect, the present invention is related to a method of forming a polycrystalline cobaltdisilicide on a silicon substrate, comprising the steps of:

depositing a layer structure on at least a part of said substrate, said layer structure comprising cobalt and a refractory metal, said substrate comprising at least a first and a second part;

depositing a getter layer on said first layer;

thereafter heating said silicon substrate on a first heating step, said first heating step being performed at a first temperature being such that said first heating step forms a silicidecobalt on said first part;

treating said substrate with at least one chemical solution, said chemical solution selectively etching the remaining non-silicidecobalt and said refractory metal and cobalt refractory metal alloys from said substrate; and thereafter

treating said substrate in a second heating step, said second heating step being performed at a higher temperature than said first temperature to thereby forming said polycrystalline cobaltdisilicide layer on said first part of said substrate.

Yet in another aspect of the invention, the formation of other near noble metal silicides (NiSi, Pd₂Si, PtSi) is disclosed.

### BRIEF DESCRIPTION OF THE DRAWINGS

FIG. 1 shows a flow sheet of a first preferred embodiment of the present invention compared with the state of the art processes, wherein: branch I represents a conventional process using only cobalt sputtering, referred to as to be the conventional Co process, branch II describes a sputtering conventional Ti/Co process, branch III represents the capping Co/Ti process according to the present invention.

FIGS. 2 represent the schematic views of the devices obtained according to the several steps performed according to the capping Co/Ti process as described in branch III of FIG. 1.

FIG. 3 represents data concerning the growth of a chemical oxide.

FIG. 4 shows the sheet resistance as a function of a first RTP temperature for the conventional Co process and the capping Co/Ti process according to the present invention.

FIG. 5 shows the sheet resistance after RTP1, RTP1/SE and RTP1/SE/RTP2 for a 15 nm thick Co film with a 8 nm Ti cap. RTP1 was varied while RTP2 temperature was constant at 700° C. (SE=selective etch).

FIG. 6 shows Raman shift versus silicide thickness for silicided lines with 3 μm linewidth and 3 μm spacing for various suicides. The stress in the Si in-between the silicided lines is proportional to the Δω value.

FIG. 7 represents oxygen concentration in the N₂ ambient during RTP for a Si dummy wafer, a wafer with Co, a wafer with Co/Ti (cap) and a wafer with Co/TiN (cap).

FIG. 8 represent the electrically measured linewidth as a function of an optically measured linewidth for the three processes described in branch I (FIG. 6a), branch II (FIG. 6b), branch III (FIG. 6c) of FIG. 1.

FIGS. 9, 10, 11 represent the cumulative probability of the sheet resistance of different gate widths for the three processes described in branch I, branch II, and III of FIG. 1 in the case of As-formed film (FIGS. 9a, 10a, 11a respectively) and in the case after a heat treatment consisting in a 750°0 C., 30 min furnace annealing (FIGS. 9b, 10b, 11b respectively).

FIG. 12 represents sheet resistance for 150 μm BF2 doped poly runners of various linewidths.

FIGS. 13, 14 represent electrical linewidth measurements on unsilicided/silicided poly runners.

FIG. 15 represents sheet resistance of 0.25 μm polylines at various lengths.

FIG. 16 represents a possible flow sheet of silicide formation.

FIG. 17 represent the cumulative probability of the sheet resistance for the conventional Co only process as formed (FIG. 17a) and a heat treatment consisting after 700° C. and 30 minutes furnace heating (FIG. 17b).

FIG. 18 represents the cumulative probability of the sheet resistance for the Co/Ti cap process according to the present invention, as formed (FIG. 18a) and after 700° C. and 30 minutes furnace heating (FIG. 18b).

### DETAILED DESCRIPTION OF SEVERAL EMBODIMENTS OF THE PRESENT INVENTION

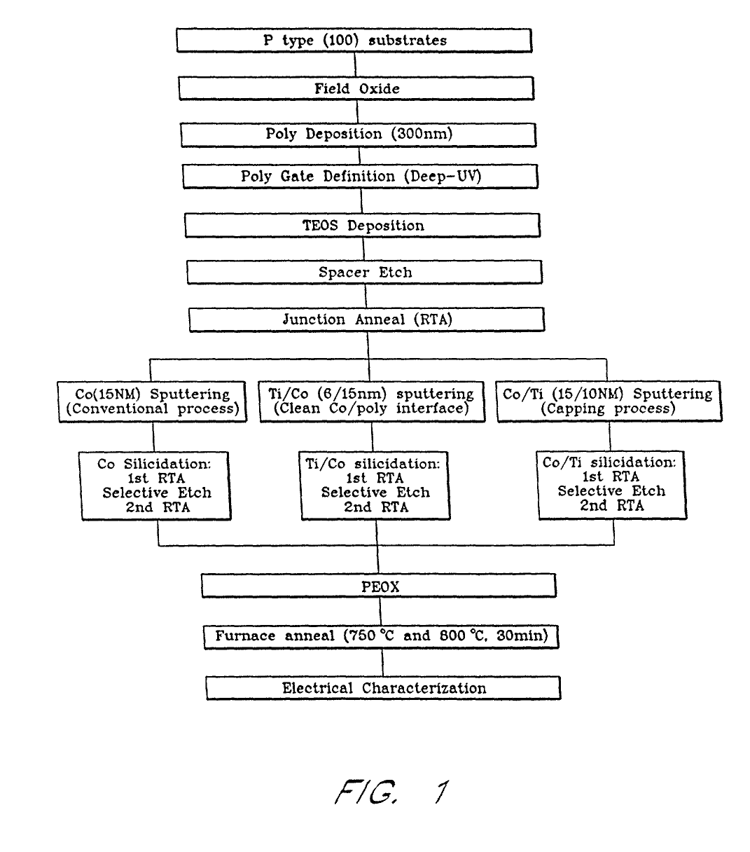

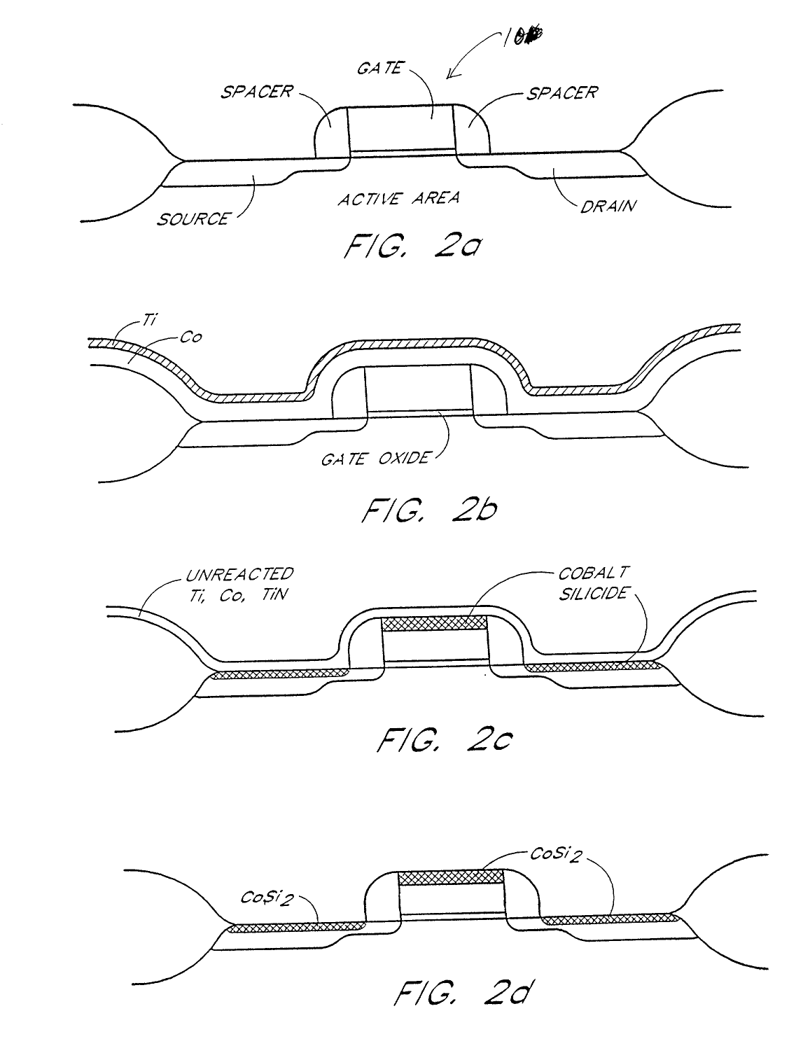

A first embodiment of the present invention is shown on FIG. 1, wherein a comparison is made with prior art processes. The major steps of transistor gate formation for a 0.25 μm CMOS process are simulated.

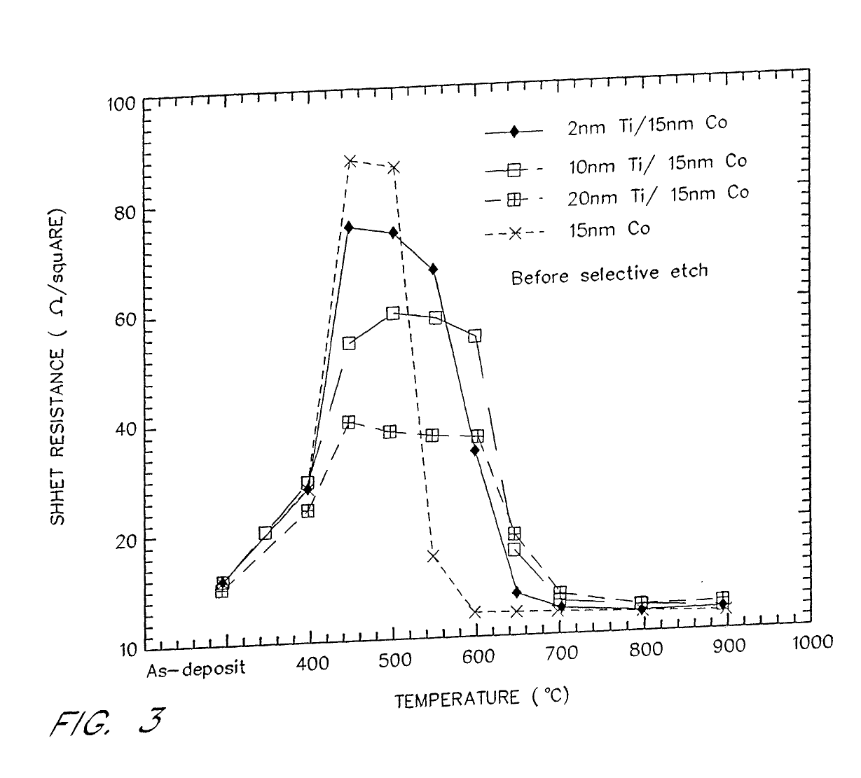

The device structures obtained after performing each step of the process according to the present invention are represented on FIGS. 2.

The starting wafers can be (100) oriented, p-type silicon wafers (see FIG. 2a). An experimental description can be as follows.

After an RCA-type cleaning in NH₄OH/H₂O₂, HCl/H₂O₂, and BHF, a 350 nm thermal oxide is grown. A 300 nm polysilicon layer is then deposited. It should be understood that the thickness of 350 nm for the oxide layer and the thickness of 300 nm for the polysilicon layer are only illustrative numbers which refer to the described experiment. Typically, silicon wafers are taken that have already been processed with an isolation module, polypatterning spacer formation and source, drain and gate doping. Similar results, as the one disclosed in the sequel, can be obtained on such processed wafers with thin (e.g. 2-10 nm) gate oxide layers and with e.g. 150-250 nm polysilicon layers.

In this first experimental embodiment, deep UV lithography was used to define 0.25 μm poly lines. Other lithography techniques could be used as well prior to silicidation. The wafers are dipped in diluted HF to remove a native oxide layer, just prior to loading into a sputter vacuum deposition system. Three process conditions are used:

Branch I:

15 nm cobalt film sputtering which is called the conventional Co process.

Branch II:

6 nm titanium film followed by a 15 nm cobalt film sputtering which is referred to as the conventional Ti/Co process,

Branch III:

15 nm cobalt film followed by 10 nm titanium film sputtering which is referred as the Co/Ti cap process according to the present invention. It can be executed with the cobalt layer thickness ranging between 5 and 50 nm and the titanium layer thickness ranging between 1 and 20 nm (FIG. 2b).

The Co and Ti layers are preferentially sputtered sequentially without breaking the vacuum conditions. Sputtering can be done on heated or non-heated chucks. For the conventional Co scheme, a standard heating using a two step RTP silicidation is employed (the first RTP at 550° C. for 30 s, and the second RTP at 700° C. for 30 s), while for the capping process a slightly modified heating process is used: the first RTP preferentially at 550° C. for 60 s, and the second RTP referentially at 700° C. for 30 s. The first RTP step can be executed within a range of 450° C. to 600° C. with the heating time ranging between 10 and 100 seconds, the second RTP being performed within a range of 600-1000° C. with the heating time ranging between 10 and 100 seconds. All the RTP's are performed in an AST SHS 2000 model.

A selective etching is performed between said first and said second RTP steps. The remaining metals or metal alloys (Co/Ti/TiN not being transformed to cobaltsilicide) after heating are selectively etched using a H₂SO₄ solution and/or a NH₄OH solution as etchants or using another solution (e.g. comprising H₃PO₄) functioning as such selective etchant. In a preferred embodiment, the etchant solutions are H₂SO₄:H₂O₂ mixture in [4:1] ratio being applied for 10 min at 90° C. and a NH₄OH:H₂O₂:H₂O mixture in [1:1:5] ratio being applied at 50° C. for 100 seconds. The application times can be varied, the application temperatures can be varied as well. In the preferred embodiment the two etchant solutions are applied as a two steps process. The Ammonia solution is taking away the polluted Ti (TiON) and Co which form during the RTP treatment. The Sulfuric acid is there to take away remnants of Co on the non-silicided areas but even more to grow a thin SiO₂ layer on top of the CoSiₓ. This chemically grown passivation layer protects the silicide during further processing. This is especially beneficial for the scalability towards narrower dimensions. FIG. 3 shows ellipsometry measurements indicating the chemical growth of an oxide layer during immersion of a cobaltsilicide in H₂SO₄-H₂O₂ mixture (indicated by 5 and 6). The formation of SiO₂ was confirmed by XPS. The layer grown is of the order of 5 nm thick. This thin oxide serves as a controlled passivation layer for the further processing, for instance during the second heating step that for instance is executed at a higher temperature than the first heating step. This thin oxide layer makes that the process of the invention yields a highly stable (thermally stable) and integer (not sensitive for contaminations) cobaltdisilicide after growth. This thin oxide can be grown thicker in the second RTP step by allowing some O₂ in the ambient of the RTP furnace.

The structure obtained according to the described process is self-aligned.

The wafers made according to this first embodiment are analyzed by four point probe, by scanning electron microscope (SEM) and by electrical linewidth measurements. Data are collected from approximately 80 structures across the wafer (FIG. 2d).

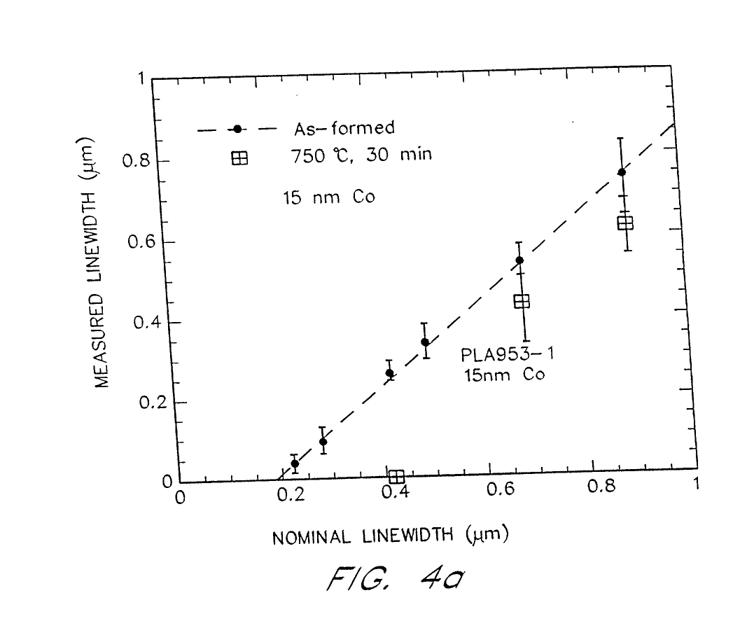

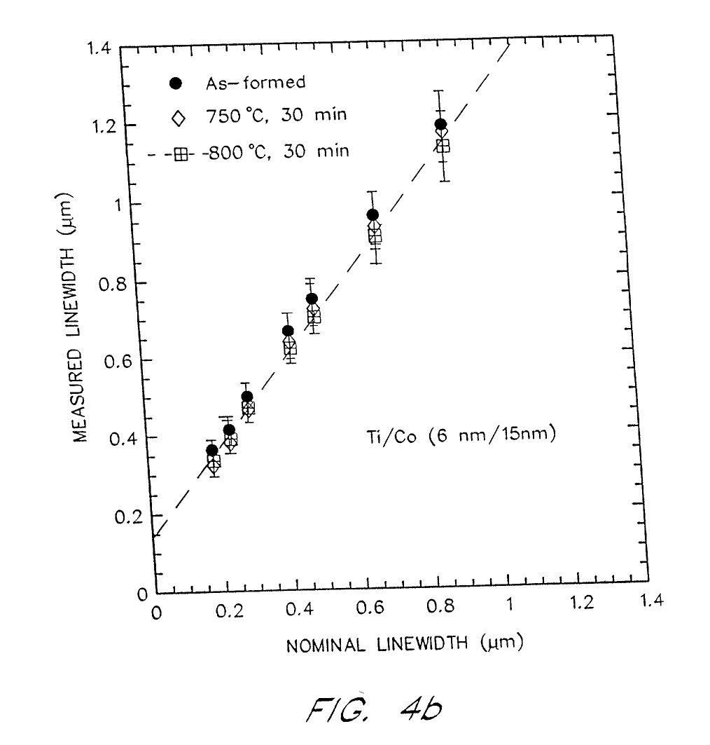

To investigate the effect of titanium capping, capping layers with various thicknesses were used. FIG. 4 depicts the sheet resistance as a function of first RTP temperature for the Co/Ti cap process compared to the conventional cobalt process. The sheet resistance is measured without removal of neither the unreacted Co nor the Ti (and/or TiN, TiN being formed by the reaction of Ti with N). The sheet resistances first go up at the same temperature (400° C.), and then go down from 550° C. to 650° C. depending on the process conditions. This can be explained by the silicide phase transformation sequence: Co->Co₂Si->CoSi->CoSi₂. The data confirm that the titanium capping layer does not significantly affect the CoSi formation within the temperature resolution of the experiment but retards the formation of CoSi₂.

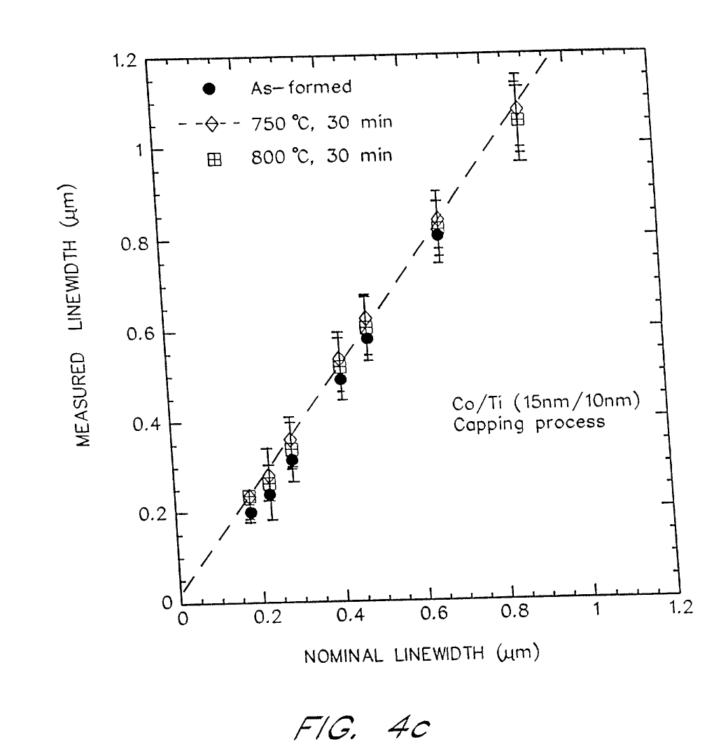

The sheet resistance versus RTP1 temperature for the Co/Ti (cap) salicidation is shown for a 15 nm Co film with a 8 nm Ti cap in FIG. 5 with more wafers at the various temperature. As compared to the Ti/Co (Ti at interface) process, the transformation temperature for Co_CoSi is reduced, and the temperature for the formation of CoSi₂ during RTP1 is increased. The specific separate phase transitions occur in a narrow temperature window. This creates a broad processing temperature window for RTP1 in which CoSi is the stable phase. The silicide thickness is independent of RTP1 temperature between 510 and 600° C. The resistivity of the CoSi equals 182 μOhm-cm and the resistivity of the CoSi₂ is 18 μOhm-cm.

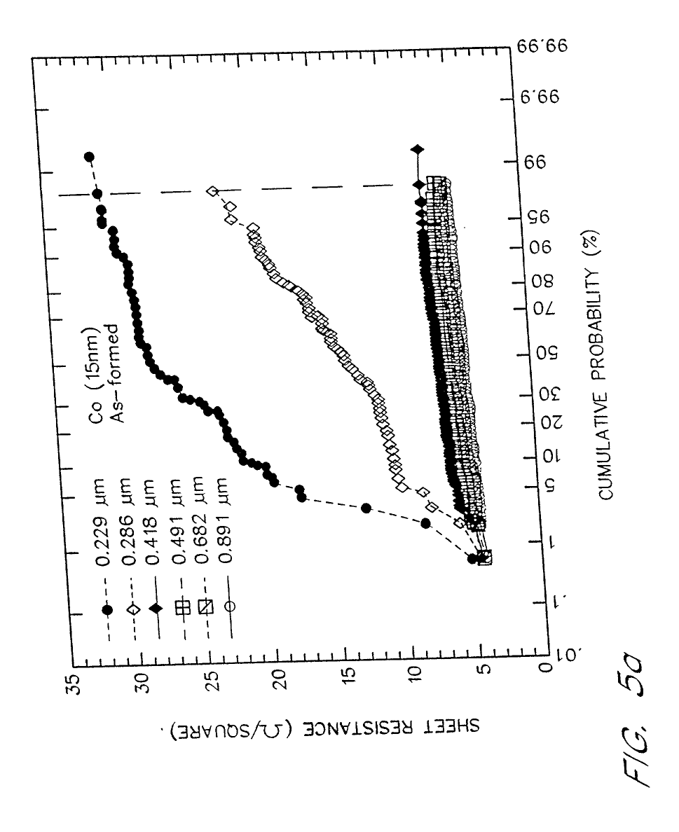

The formed CoSi₂ film is polycrystalline. This is essential in view of the stress build-up in the underlying Si. FIG. 6 shows the stress in the Si generated by the CoSi₂. The stress is low in the case of the Co/Ti (cap) process as compared to the Ti/Co (Ti at interface). Due to the polycrystalline nature of the CoSi₂ formed by the Co/Ti (cap) process, the stress build up is only due to difference in thermal expansion coefficient in contrast to to the epitaxial alignment as in case of the Ti/Co (Ti at interface).

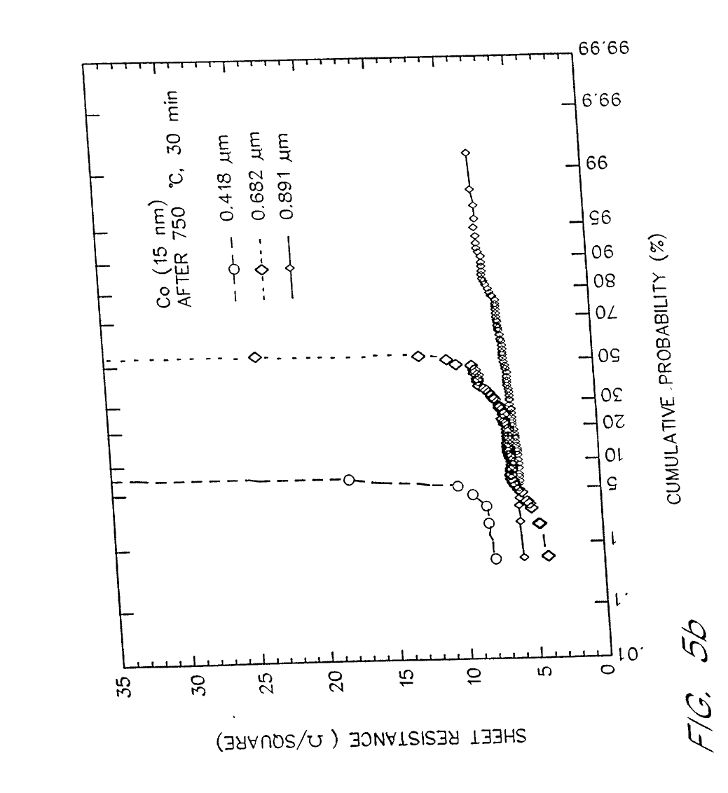

The role of the Ti cap layer in the Co-silicidation process is studied by monitoring the ambient during RTP1. The main species of interest are the evolution of the O₂ content in the ambient, the H₂O content and the CO₂ content. It is important to notice that the wafer itself plays an active role by adsorbing and desorbing these species during processing. The O₂ level during Co silicidation (RTP1) is depicted in FIG. 7. Whereas the steady O₂ level of state of the art RTP systems is less than 1 ppm, if sufficient time is reserved for purging, the Ti cap layer causes a drop in the O₂ level below 0.1 ppm (measurement limit). The chemical activity of the Ti is essential. A TiN cap is far less efficient. Thus Ti is an efficient getter layer.

Similar measurements are made for CO₂ and H₂O. CO₂ adsorbs significantly more on Co than on a Ti or TiN cap. Both Ti and TiN capping layers are efficient in stopping the outgassing of H₂O. It should be noted, however, that H₂O will be captured by the Ti. TiN can not play that role, as shown in the reference M. Yoshimaru et al, IEEE 1995. For adsorbed species on the wafer the diffusion barrier properties of the TiN are a draw back as compared to the chemical activity of the Ti layer. Therefore the presence of adsorbed H₂O can lead to thinning effects in the case of a TiN cap along SiO₂ edges.

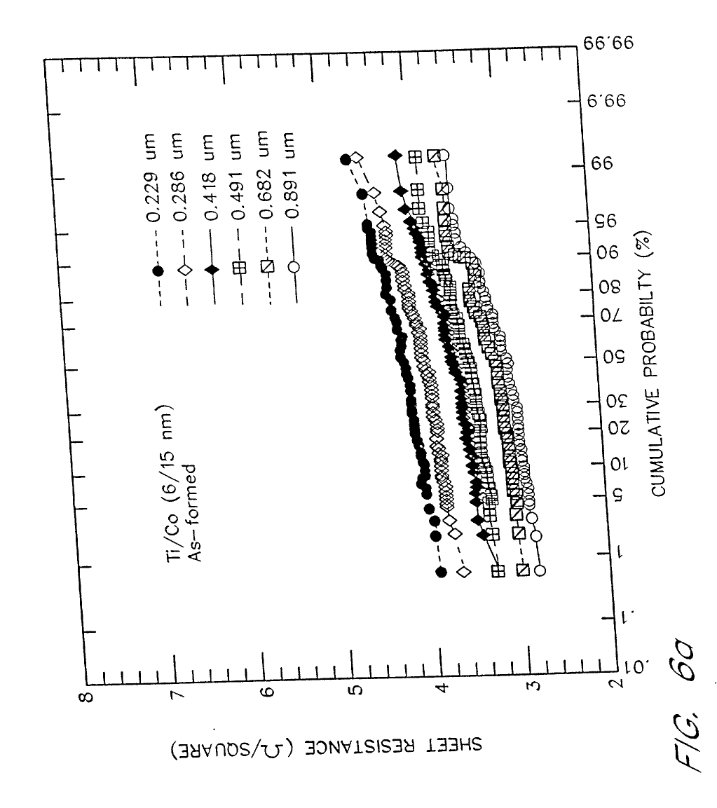

FIGS. 8a, 8b, and 8c depict the electrically measured linewidth versus optically measured linewidth for the conventional cobalt process for the conventional Ti/Co process and for the capping Co/Ti process of the invention. The linewidth is obtained based on the following formula:

W=L(I/V)×R_{vdp}

where L is the length of the bridge resistor, I is the forced current, V is the measured voltage drop, and R_{vdp} is the sheet resistance measured from van der Pauw structure. Comparing FIGS. 8b and 8c, one can find that even for the as-formed case the conventional process gives a strong apparent linewidth loss, which is believed to result from non-uniform silicide formation. The As formed lines using the Co/Ti cap process show the good characteristics. The result is even more prominent after back end processing. After 750° C. furnace anneal for 30 min, the cap process does not give a notable degradation of the sheet resistance of the lines. The conventional process, however, yields a significant increase in sheet resistance (decrease in linewidth) for the narrowest lines for the same 750° C. anneal.

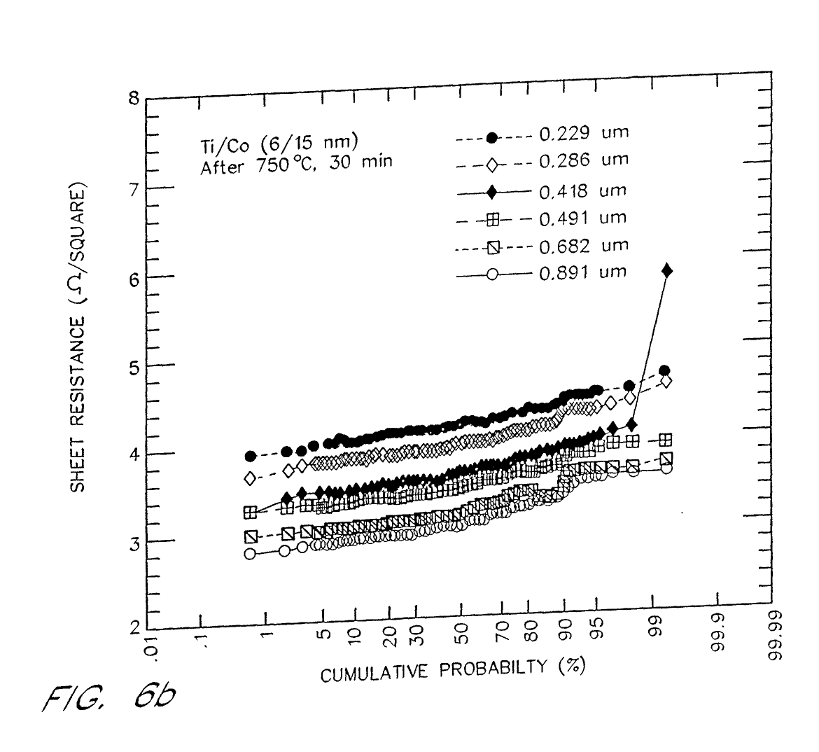

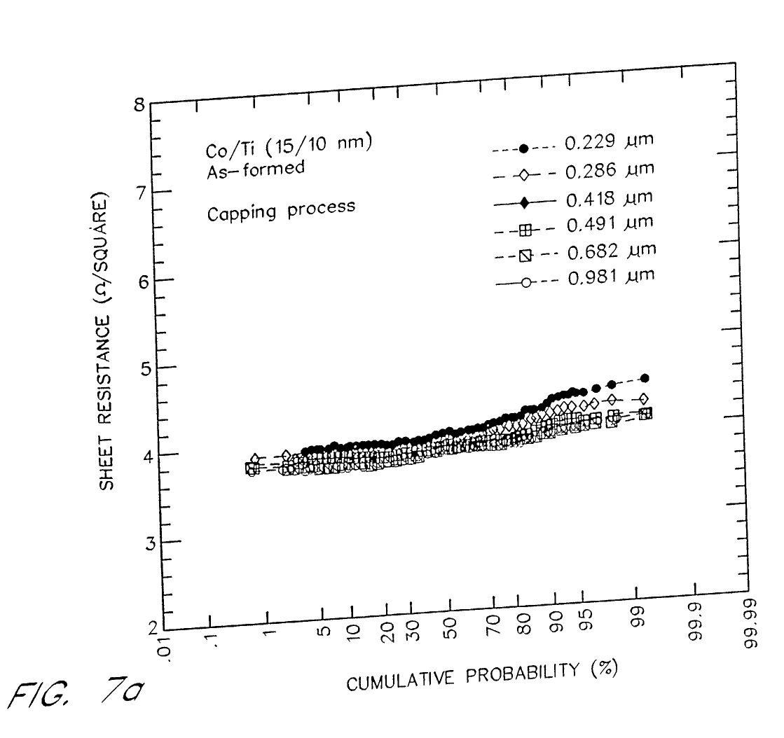

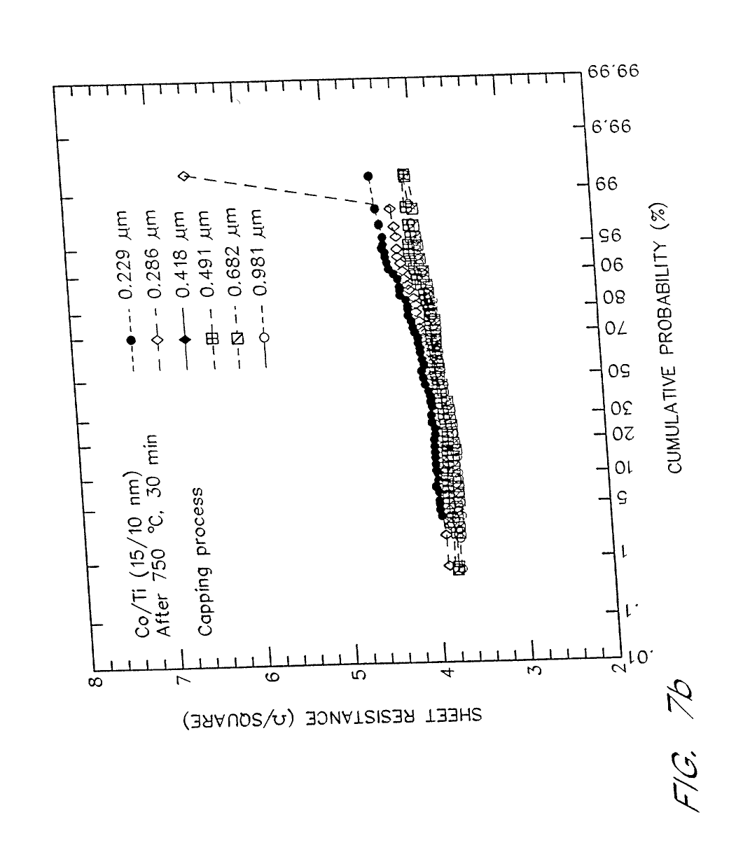

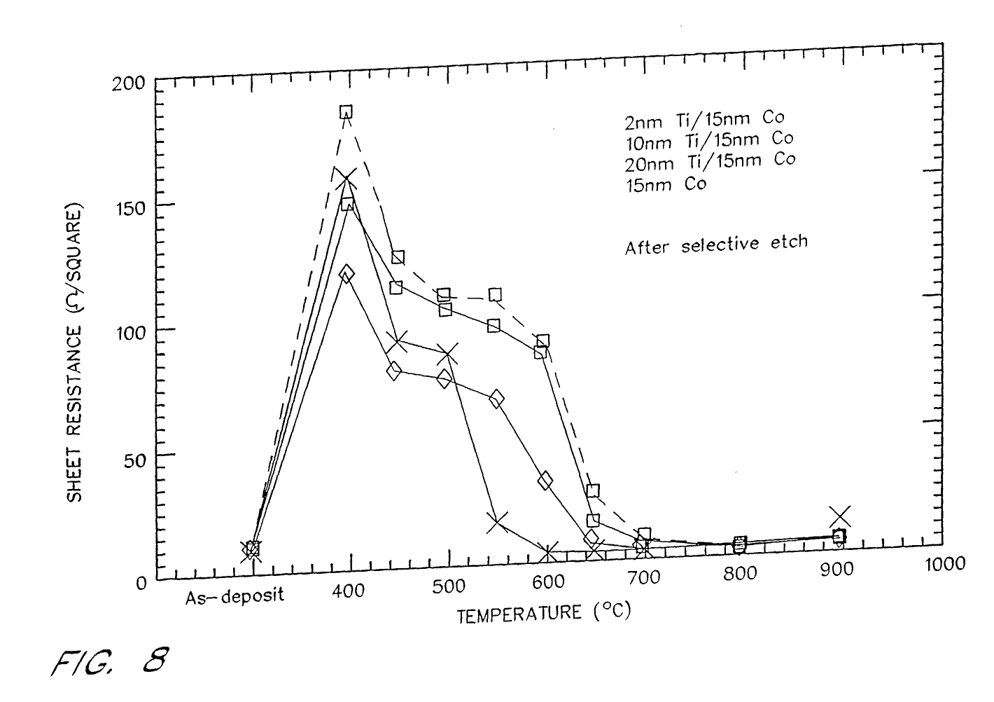

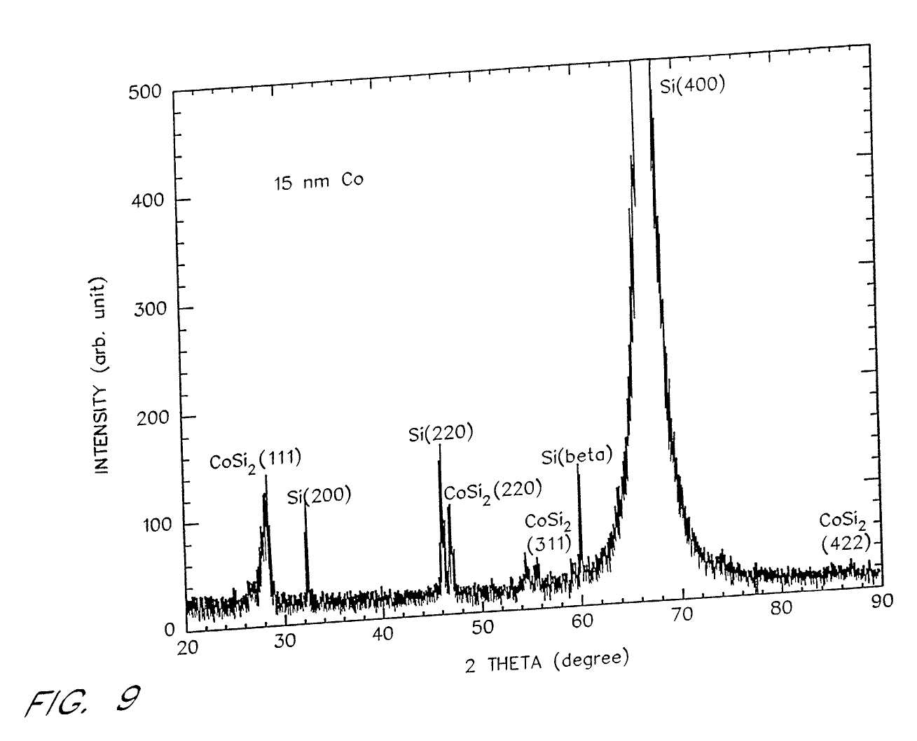

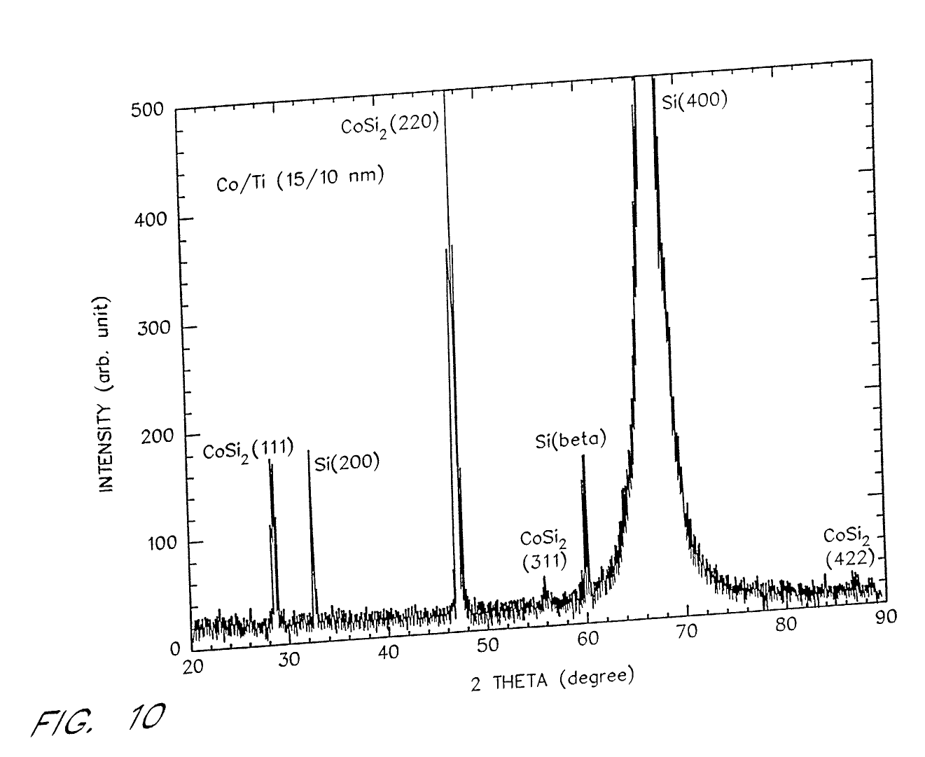

FIGS. 9, 10, and 11 give the statistical data of sheet resistance for different linewidths for the conventional Co process (FIGS. 9a and 9b), for the conventional Ti/Co process (FIGS. 10a and 10b) as well as for Co/Ti cap process (FIG. 11a and 11b) respectively. Carefully examining FIGS. 9 and 10, one can find that thin CoSi₂ is not uniformly formed on the narrowest lines. For lines narrower than 0.3 μm, there is a large spread in the distribution. After 750° C., 30 min furnace anneal, only the widest lines show good thermal activity. In contrast, the Co/Ti cap process (FIG. 11a) results in very tight sheet resistance distribution for all defined lines. After 750° C., 30 min furnace anneal, no significant sheet resistance changes were observed (FIG. 9b). A very tight data distribution is observed for both as formed and heat treated films when the capping process is employed. The thermal stability improvement is due to the uniformity improvement of the silicide as formed on the narrow lines. Therefore, for thicker films and wider lines, this effect is not as pronounced.

According to this embodiment of the invention, diodes have been fabricated with the Co/Ti (cap) process. Typical leakage currents are <10⁻⁸ A/cm² for large square diodes, 10⁻¹¹ A/cm perimeter leakage on long meander diodes. Due to the low stress induced by the silicide in the underlying Si, the formation of dislocations is avoided resulting in low leakage currents.

FIG. 12 represents according to the first embodiment of the present invention electrical data of the Co-silicide process with Ti cap (the Co/Ti process) on BF₂ doped 150 μm long poly runners with nitride spacers. The runners were patterned by state of the art DUV litho. All measurements of all chips are presented. There is no linewidth dependence. The yield of the narrow lines is very high. Similar results are obtained with oxide spacers and for As doping.

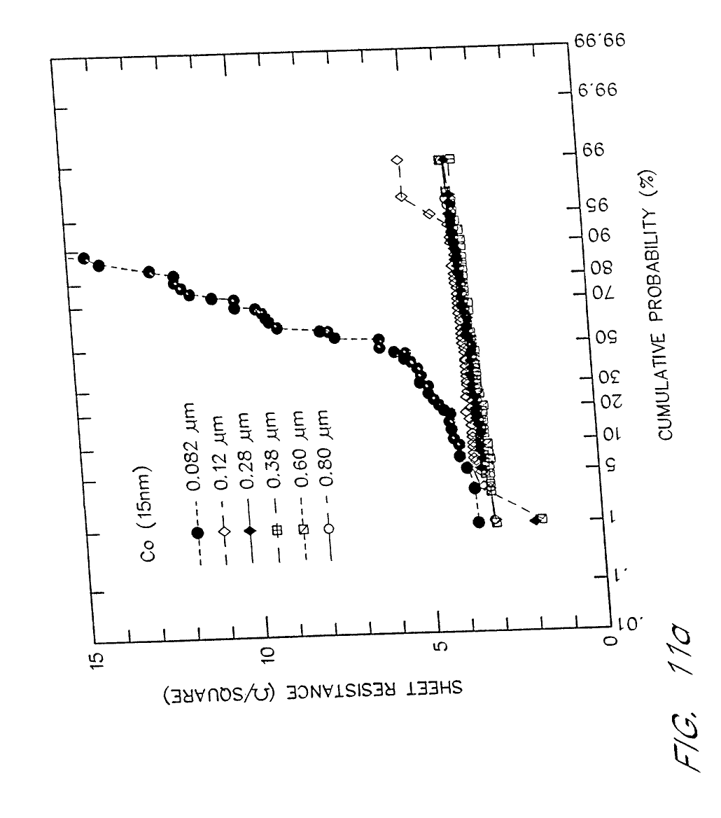

Extensive electrical linewidth measurements were performed on the poly runners in order to nail down any process related non-uniformity. FIGS. 13 and 14 compare the electrical linewidth measurements of non-silicided and silicided lines. The electrical linewidth was measured from the ratio of the narrow line resistance and large Van Der Pauw structures for the various linewidths. Detailed inspection of the data shows that the silicidation process hardly contributes to the spread of the data. Indeed the small variations over the wafers are reflecting the variations of patterning. It means that the non-uniformities that are expected as a result of RTP are not affecting the uniformity of the process. This is an important consequence of the large RTP1 process window of the Co/Ti cap process. FIG. 15 shows performance of the silicide module for very long poly meanders of 0.25 μm width.

In a best mode execution of the silicide formation process of the invention for a 0.25 μm CMOS process the following description is given. Typically, silicon wafers are taken that have already been processed with an isolation module, polypatterning spacer formation and source, drain and gate doping. One should start with a wet etch of remaining oxides on the wafer part that is to be silicided. Such oxides can be the implantation oxide and TEOS, the wet etch to be done in a solution (H₂O) of 2% HF during 80 seconds. Thereafter and foregoing loading of the silicon wafer in the deposition chamber (Endura Applied), a 20 seconds dip in a solution (H₂O) 2% HF is performed. Alternatively, a sputter cleaning in the deposition chamber can be applied. Thereafter, a deposition of 15 nm cobalt with 8 nm titanium capping layer is performed in the deposition chamber (Endura Applied). The Co-silicidation is performed with a RTP1 step at 550° C. during 60 seconds in a N₂ ambient, followed by a selective etch of 90 seconds in a NH₄OH/H₂O₂/H₂O solution (1/1/5) at 50° C. followed by a 10 minutes H₂SO₄/H₂O₂ solution (4/1) at 90° C. The RTP2 step is performed at 700° C. during 30 seconds in a N₂ ambient.

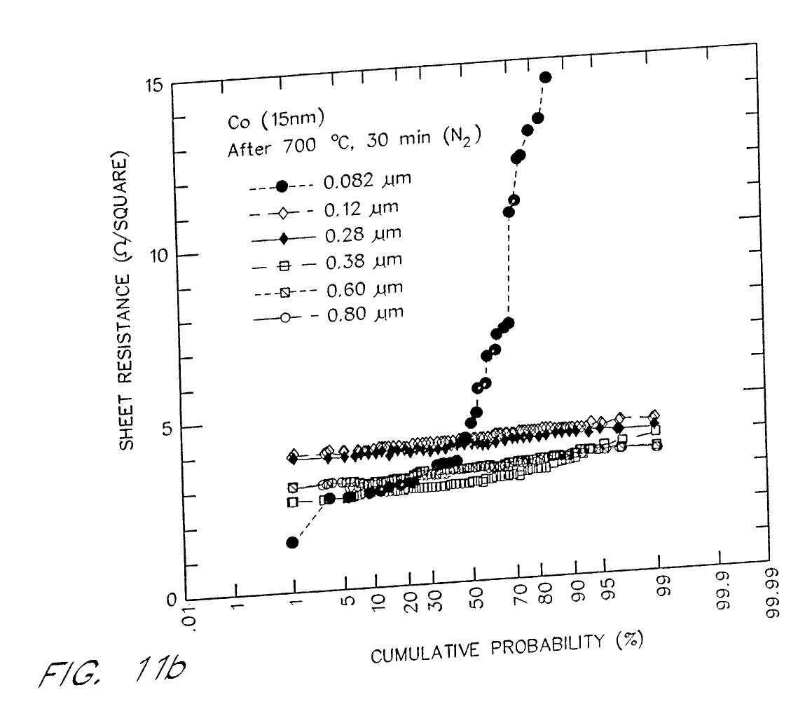

FIG. 16 represents a flowsheet of salicide formation on a silicon wafer according to this best mode example.

According to another preferred embodiment of the present invention for a 0.1 μm CMOS process, the formation of contacts on 0.08 μm polysilicon gates on a MOS transistor using the CoSi₂ salicide process according to the present invention is described in the sequel. The experiments do not show any counter evidence that the process cannot be extended to smaller gate lengths such as 0.07 μm or 0.05 μm or even smaller gate lengths. The process as described in the second embodiment of the present invention has been successfully implemented in a 0.1 μm CMOS development work on a pilot CMOS line.

The silicon substrates used in the second preferred embodiment are (100) oriented, 5 inch device wafers. After modified clean, a thin gate oxide (3-10 nm) and a polysilicon layer of 200 nm were deposited. The test patterns are defined with direct e-beam lithography, followed by RIE etching of polysilicon. Both TEOS spacer (100 nm) and nitride spacer (150 nm) were investigated. S/D formation was done by As (NMOS) and BF₂ (PMOS) implantation respectively. Two process conditions were used: (1) 15 nm Co films, which is the conventional Co process; (2) 15 nm Co followed by 10 nm Ti films, which is referred to the capping Co/Ti process.

A two-step RTP silicidation process was employed. Furnace heating at 700° C. for 30 min was chosen to evaluate the thermal stability of the films. The remaining metal (Co, Ti, TiN) after heating is selectively etched using H₂SO₄ and NH₄OH solutions as etchants. Thus, the structure formed by this process is self-aligned. Electrical measurements were performed with an average of 49 points across the wafers. The wafers were also analyzed by plan-view and cross-section SEM after full electrical characterization.

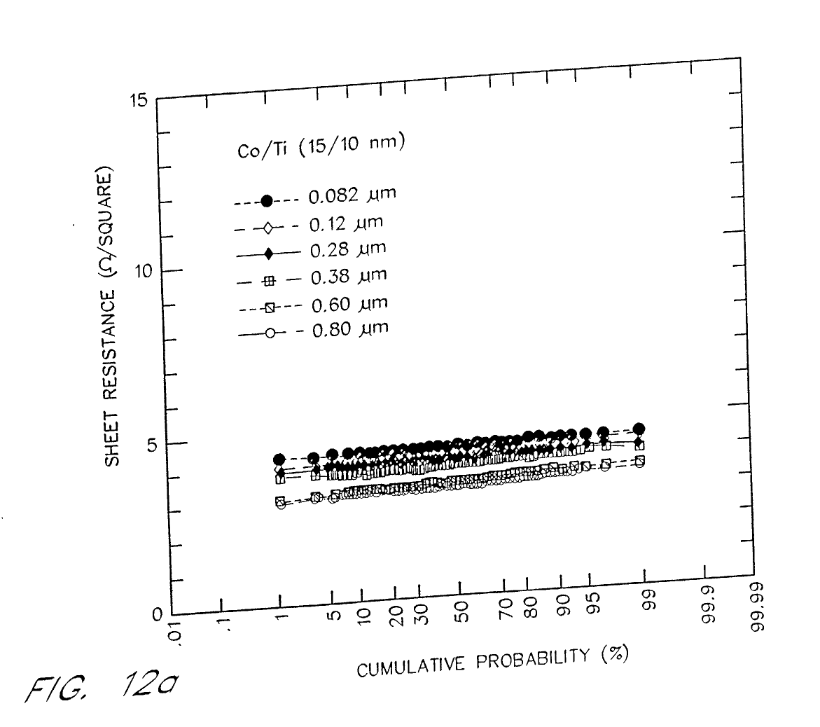

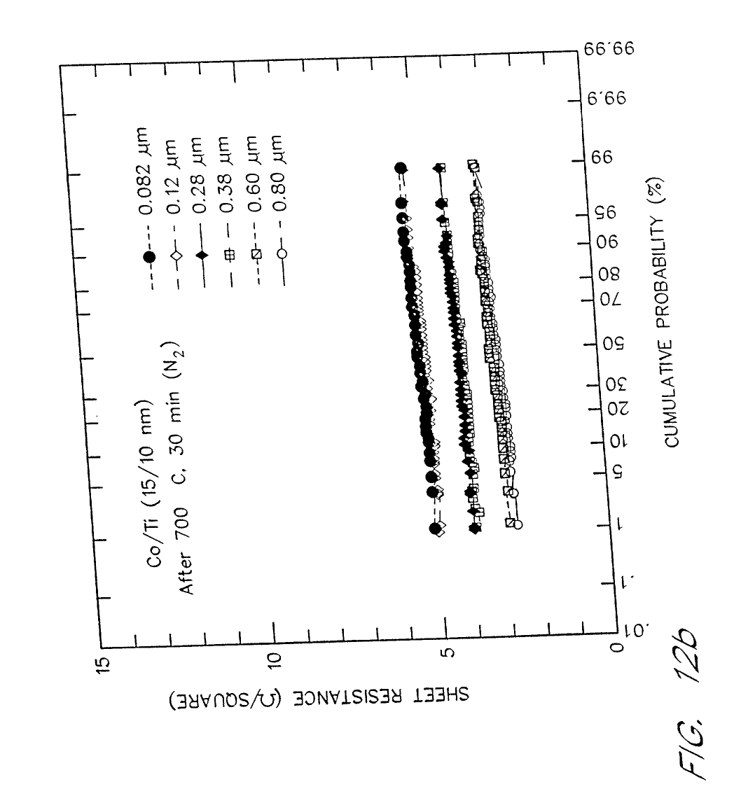

FIGS. 17 and 18 give the statistical data of sheet resistance for both Co and Co/Ti processes with different linewidths. Important observations can be obtained. First, a very tight data distribution is observed for all measured lines when Co/Ti process is employed (FIG. 18a). Second, it is difficult to form thin CoSi₂ on sub 0.1 μm poly Si runner using the conventional process (FIG. 17a). Third, no significant sheet resistance change were observed after moderate temperature furnace anneal.

What is claimed is:

1. A method of forming a polycrystalline cobaltdisilicide (CoSi₂) on a silicon substrate, comprising the steps of:
depositing a first layer comprising cobalt on at least a part of said substrate, said part comprising at least a first and a second part;
depositing a metal getter layer on said first layer;
thereafter heating said silicon substrate in a first heating step, said first heating step being performed at a first temperature being such that a silicidecobalt is formed on said first part;
treating said substrate with at least one chemical solution to remove unwanted matter from said substrate; and thereafter
heating said substrate in a second heating step to thereby form said polycrystalline cobaltdisilicide layer on said first part of said substrate.

2. The method as recited in claim 1, wherein said silicidecobalt is cobaltsilicide (CoSi).

3. The method as recited in claim 1, wherein during the chemical solution treatment, a passivation layer is grown on top of the silicidecobalt being formed on said first part of said substrate.

4. The method as recited in claim 3, wherein said passivation layer is a thin layer.

5. The method as recited in claim 4, wherein said passivation layer is having a thickness of about 5 nm.

6. The method as recited in claim 1, wherein said getter layer consists essentially of a refractory metal.

7. The method as recited in claim 6, wherein said refractory metal is titanium.

8. The method as recited in claim 1, wherein said chemical solution comprises NH₄OH.

9. The method as recited in claim 1, wherein said chemical solution comprises H₂SO₄.

10. The method as recited in claim 1, wherein said first layer has a thickness in the range of 5-50 nm, and said titanium layer has a thickness in the range of 1-50 nm.

11. The method as recited in claim 1, wherein said first layer has a thickness of 15 nm, and said titanium layer has a thickness of 8 nm.

12. The method as recited in claim 1, wherein said second heating step is being performed at a higher temperature than said first temperature.

13. The method as recited in claim 1, wherein said first heating step is performed in the range of 400-700° C. for a period of time comprised between 10-100 seconds and said second heating step is performed in the range of 600-1000° C. for a period of time between 10-100 seconds.

14. The method as recited in claim 1, wherein said first heating step is performed at 550° C. for a period of time of 60 seconds and said second heating step is performed at 700° C. for a period of time of 30 seconds.

15. The method as recited in claim 1, wherein said deposition steps are performed by sputter deposition in a vacuum system without breaking the vacuum conditions inbetween subsequent deposition steps.

16. The method as recited in claim 1, wherein said polycrystalline cobaltdisilicide is a self-aligned cobaltdisilicide on a metal oxide semiconductor transistor in a silicon substrate, said transistor having an actual gate length of about 0.25 μm or smaller and having a source region, a drain region, and a gate region.

17. The method as recited in claim 16, further comprising the steps of:
defining an active area within said silicon substrate;
growing an oxide on at least within part of said active area of said substrate;
depositing a polysilicon layer on said oxide; and
defining said gate region, said source region, and said drain region of said transistor within said active area, said gate region, said source region and said drain region forming said first part.

18. The method as recited in claim 1, wherein said polycrystalline cobaltdisilicide is a self-aligned cobaltdisilicide on a metal oxide semiconductor transistor in a silicon substrate, said transistor having an actual gate length of about 0.18 μm or smaller and having a source region, a drain region, and a gate region.

19. A method as recited in claim 18, further comprising the steps of:
defining an active area within said silicon substrate;
growing an oxide on at least within part of said active area of said substrate;
depositing a polysilicon layer on said oxide; and
defining said gate region, said source region, and said drain region of said transistor within said active area, said gate region, said source region and said drain region forming said first part.

20. A method of forming a polycrystalline cobaltdisilicide on a silicon substrate, comprising the steps of:
depositing a layer structure on at least a part of said substrate, said layer structure comprising cobalt and a refractory metal, said substrate comprising at least a first and a second part;
thereafter heating said silicon substrate in a first heating step, said first heating step being performed at a first temperature being such that said first heating step forms a silicidecobalt on said first part;
treating said substrate with at least one chemical solution, said chemical solution selectively removing the remaining non-silicidecobalt and said refractory metal and cobalt refractory metal alloys from said substrate; and thereafter
heating said substrate in a second heating step to thereby form said polycrystalline cobaltdisilicide layer on said first part of said substrate.

21. The method as recited in claim 20, wherein said deposition step is executed by sputter deposition in a vacuum system using a sputter target comprising a mixture of cobalt and said refractory metal.

22. The method as recited in claim 20, wherein said second heating step is being performed at a higher temperature than said first temperature.

23. A method of forming a polycrystalline nickelsilicide (NiSi) on a silicon substrate, comprising the steps of:
depositing a first layer comprising nickel on at least a part of said substrate, said part comprising at least a first and a second part;
depositing a metal getter layer on said first layer;
thereafter heating said silicon substrate in a first heating step, said first heating step being performed at a first temperature being such that a silicidenickel is formed on said first part;
treating said substrate with at least one chemical solution, said chemical solution selectively removing the remaining non-silicidenickel and/or said getter metal and/or nickel and/or nickel-getter-metal alloys from said substrate; and thereafter
heating said substrate in a second heating step to thereby form said polycrystalline nickelsilicide layer on said first part of said substrate.

24. A method of forming a polycrystalline palladiumsilicide (Pd₂Si) on a silicon substrate, comprising the steps of:
depositing a first layer comprising palladium on at least a part of said substrate, said part comprising at least a first and a second part;
depositing a metal getter layer on said first layer;
thereafter heating said silicon substrate in a first heating step, said first heating step being performed at a first temperature being such that a silicidepalladium is formed on said first part;
treating said substrate with at least one chemical solution, said chemical solution selectively removing the remaining non-silicidepalladium and/or said getter metal and/or palladium and/or palladium-getter-metal alloys from said substrate; and thereafter
heating said substrate in a second heating step to thereby form said polycrystalline palladiumsilicide layer on said first part of said substrate.

25. A method of forming a polycrystalline platinumsilicide (PtSi) on a silicon substrate, comprising the steps of:
depositing a first layer comprising platinum on at least a part of said substrate, said part comprising at least a first and a second part;
depositing a metal getter layer on said first layer;
thereafter heating said silicon substrate in a first heating step, said first heating step being performed at a first temperature being such that a silicideplatinum is formed on said first part;
treating said substrate with at least one chemical solution, said chemical solution selectively removing the remaining non-silicideplatinum and/or said getter metal and/or platinum and/or platinum-getter-metal alloys from said substrate; and thereafter
heating said substrate in a second heating step to thereby form said polycrystalline platinumsilicide layer on said first part of said substrate.

26. The method as recited in claim 1, wherein said chemical solution can selectively remove remaining non-silicidecobalt, said getter metal, cobalt, cobalt-getter-metal alloys from said substrate.
